(19) United States
(12) Patent Application Publication
(10) Pub. No.: US 2026/0188412 A1
(43) Pub. Date: Jul. 2, 2026

(54) SEMICONDUCTOR DEVICE AND METHOD

(71) Applicants: Samsung Electronics Co., Ltd., Suwon-si (KR); Research & Business Foundation SUNGKYUNKWAN UNIVERSITY, Suwon-si (KR)

(72) Inventors: Byungwoo BANG, Suwon-si (KR); Yoonyul YOO, Suwon-si (KR); Hun Seong CHOI, Suwon-si (KR); Jungrae KIM, Seoul (KR)

(73) Assignees: Samsung Electronics Co., Ltd., Suwon-si (KR); Research & Business Foundation SUNGKYUNKWAN UNIVERSITY, Suwon-si (KR)

(21) Appl. No.: 19/241,238

(22) Filed: Jun. 17, 2025

(30) Foreign Application Priority Data
Dec. 26, 2024 (KR) 10-2024-0197646

(51) Int. Cl. G11C 29/42; G06F 11/10; G11C 29/52; H10B 80/00

(52) U.S. Cl. CPC G11C 29/42; G06F 11/1044; G06F 11/1048; G11C 29/52; H10B 80/00

(57) ABSTRACT

A semiconductor device includes a base die, and a plurality of memory dies stacked on the base die, wherein the plurality of memory dies is configured to divide and store first bits that represent data of a data block, the plurality of memory dies is configured to divide and store second bits that represent an error correcting code (ECC) of the data block, in response to the data block being requested to be accessed, the plurality of memory dies is configured to transmit the first bits and the second bits of the requested data block to the base die, and the base die is configured to determine whether an error occurs in the first bits by using the second bits.

### CROSS-REFERENCE TO RELATED APPLICATIONS

This application claims the benefit under 35 USC § 119(a) of Korean Patent Application No. 10-2024-0197646, filed on Dec. 26, 2024 in the Korean Intellectual Property Office, the entire disclosure of which is incorporated herein by reference for all purposes.

### BACKGROUND

### 1. Field

The following description relates to a semiconductor device and method.

### 2. Description of Related Art

Modern electronic devices may require high performance and energy efficiency, and semiconductor integrated circuit (IC) technology may meet these demands. Particularly, high-performance computing devices, artificial intelligence (AI) processors, graphics processing units (GPUs), data centers, and mobile devices may require higher processing speed and more data processing capability.

To meet these demands, multi-die or system-in-package (SIP) technology may be used in the semiconductor technology field. These technologies may allow multiple processors, memories, and various functional blocks to be integrated and operated within a single package, contributing to performance improvement and space efficiency. In high-performance systems, it may be important to optimize data transfer speed between processors and multiple memories while maintaining reliability.

### SUMMARY

This Summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter.

In one or more general aspects, a semiconductor device includes a base die, and a plurality of memory dies stacked on the base die, wherein the plurality of memory dies may be configured to divide and store first bits that represent data of a data block, the plurality of memory dies may be configured to divide and store second bits that represent an error correcting code (ECC) of the data block, in response to the data block being requested to be accessed, the plurality of memory dies may be configured to transmit the first bits and the second bits of the requested data block to the base die, and the base die may be configured to determine whether an error occurs in the first bits by using the second bits.

The base die may be either one of a buffer die and a processor die.

A number of the plurality of memory dies may be determined as a power of 2, and the first bits and the second bits of the data block may be stored in the plurality of memory dies.

The plurality of memory dies may include a plurality of channels that operates independently of each other, and the base die may be configured to store the first bits and the second bits of the data block in a channel corresponding to the data block among the plurality of channels.

Each of the plurality of memory dies may include a plurality of channel partitions, and the first bits and the second bits of the data block may be stored in any one of the plurality of channel partitions.

Whether an error occurs in the data of the data block may be determined using the second bits, based on the first bits stored in channel partitions corresponding to the data block among the plurality of channel partitions.

The data of the data block stored in the channel partitions may include one or more symbols, and, based on each of the one or more symbols, whether an error occurs in the first bits corresponding to each symbol may be determined.

The plurality of channel partitions may be connected to a command pin that corresponds to the data block and may be configured to receive a memory command for the data block from the base die.

The second bits may be stored in redundancy areas included in the plurality of channel partitions.

The base die may include a logic circuit configured to receive the first bits that represent the data of the data block and are divided and stored in each of the plurality of memory dies and the second bits that represent the ECC, in response to receiving an access request for the data block from a host, and a decoder configured to decode the ECC using the first bits, and whether an error occurs in the first bits may be determined based on the ECC.

The decoder may be configured to determine whether an error occurs in the first bits by using the first bits, based on the second bits stored in channel partitions corresponding to the data block among the plurality of channel partitions.

The decoder may be configured to analyze the first bits and the second bits as symbols having a size greater than or equal to a predetermined number of bits, determine whether an error occurs in the first bits, and correct the occurred error.

Thelogic circuit may be configured to transmit a memory command requesting the first bits and the second bits to channel partitions corresponding to the data block storing the first bits among the plurality of channel partitions through command pins corresponding to the data block.

Each of the plurality of memory dies may be configured to store the first bits or the second bits.

In one or more general aspects, a method of operating a semiconductor device includes receiving an access request for a data block from a host, transmitting first bits that represent data of the data block and are divided and stored in each of a plurality of memory dies and second bits that represent an error correction code (ECC) from the plurality of memory dies to a base die, and determining whether an error occurs in the first bits by using the second bits.

A number of the plurality of memory dies may be determined as a power of 2, and the first bits and the second bits of the data block may be stored in the plurality of memory dies.

The plurality of memory dies may include a plurality of channels that operates independently of each other, and the base die may be configured to store the first bits and the second bits of the data block in a channel corresponding to the data block among the plurality of channels.

Each of the plurality of memory dies may include a plurality of channel partitions, and the first bits and the second bits of the data block may be stored in any one of the plurality of channel partitions.

The determining of whether an error occurs may include determining whether an error occurs in the data of the data block by using the second bits, based on the first bits stored in channel partitions corresponding to the data block among the plurality of channel partitions.

The determining of whether an error occurs may include analyzing the first bits and the second bits as symbols having a size greater than or equal to a predetermined number of bits, determining whether an error occurs in the first bits, and correcting the occurred error.

Other features and aspects will be apparent from the following detailed description, the drawings, and the claims.

### BRIEF DESCRIPTION OF THE DRAWINGS

FIG. 1 illustrates an example of a semiconductor device.

FIG. 2 illustrates an example of a plurality of memory dies included in a semiconductor device.

FIG. 3 illustrates an example of reference memory channels.

FIG. 4 illustrates an example of an operation of dividing and storing first bits and second bits by a plurality of memory dies.

FIGS. 5 and 6 illustrate examples of a plurality of partitions.

FIGS. 7 and 8 illustrate examples of a correspondence between a data block, reference memory channels, and partitions.

FIGS. 9 and 10 illustrate examples of an operation of transmitting first bits and second bits

FIGS. 11A and 11B illustrate examples of an operation of determining whether an error occurs in data by using second bits.

FIG. 12 illustrates an example of a redundancy area for storing second bits.

FIGS. 13 and 14 illustrate examples of an operation of transmitting bits and memory commands.

FIGS. 15 and 16 illustrate examples of a semiconductor device.

FIG. 17 illustrates an example of a semiconductor device.

FIG. 18 illustrates an example of an operating method of a semiconductor device.

FIG. 19 illustrates an example of a semiconductor device.

Throughout the drawings and the detailed description, unless otherwise described or provided, the same drawing reference numerals may be understood to refer to the same elements, features, and structures. The drawings may not be to scale, and the relative size, proportions, and depiction of elements in the drawings may be exaggerated for clarity, illustration, and convenience.

### DETAILED DESCRIPTION

The following detailed description is provided to assist the reader in gaining a comprehensive understanding of the methods, apparatuses, and/or systems described herein. However, various changes, modifications, and equivalents of the methods, apparatuses, and/or systems described herein will be apparent after an understanding of the disclosure of this application. For example, the sequences of operations described herein are merely examples, and are not limited to those set forth herein, but may be changed as will be apparent after an understanding of the disclosure of this application, with the exception of operations necessarily occurring in a certain order. Also, descriptions of features that are known after an understanding of the disclosure of this application may be omitted for increased clarity and conciseness.

As used herein, the term “and/or” includes any one and any combination of any two or more of the associated listed items. The phrases “at least one of A, B, and C”, “at least one of A, B, or C”, and the like are intended to have disjunctive meanings, and these phrases “at least one of A, B, and C”, “at least one of A, B, or C”, and the like also include examples where there may be one or more of each of A, B, and/or C (e.g., any combination of one or more of each of A, B, and C), unless the corresponding description and embodiment necessitates such listings (e.g., “at least one of A, B, and C”) to be interpreted to have a conjunctive meaning.

Throughout the specification, when a component or element is described as “on,” “connected to,” “coupled to,” or “joined to” another component, element, or layer, it may be directly (e.g., in contact with the other component, element, or layer) “on,” “connected to,” “coupled to,” or “joined to” the other component element, or layer, or there may reasonably be one or more other components elements, or layers intervening therebetween. When a component or element is described as “directly on,” “directly connected to,” “directly coupled to,” or “directly joined to” another component element, or layer, there can be no other components, elements, or layers intervening therebetween. Likewise, expressions, for example, “between” and “immediately between” and “adjacent to” and “immediately adjacent to” may also be construed as described in the foregoing.

The terminology used herein is for describing various examples only and is not to be used to limit the disclosure. The articles “a,” “an,” and “the” are intended to include the plural forms as well, unless the context clearly indicates otherwise. As non-limiting examples, terms “comprise” or “comprises,” “include” or “includes,” and “have” or “has” specify the presence of stated features, numbers, operations, members, elements, and/or combinations thereof, but do not preclude the presence or addition of one or more other features, numbers, operations, members, elements, and/or combinations thereof, or the alternate presence of an alternative stated features, numbers, operations, members, elements, and/or combinations thereof. Additionally, while one embodiment may set forth such terms “comprise” or “comprises,” “include” or “includes,” and “have” or “has” to specify the presence of stated features, numbers, operations, members, elements, and/or combinations thereof, other embodiments may exist where one or more of the stated features, numbers, operations, members, elements, and/or combinations thereof are not present.

Unless otherwise defined, all terms, including technical and scientific terms, used herein have the same meaning as commonly understood by one of ordinary skill in the art to which the present disclosure pertains and after an understanding of the present disclosure. Terms, such as those defined in commonly used dictionaries, should be construed to have meanings matching with contextual meanings in the relevant art and the present disclosure, and are not to be construed to have an ideal or excessively formal meaning unless otherwise defined herein. The use of the term “may” herein with respect to an example or embodiment, e.g., as to what an example or embodiment may include or implement, means that at least one example or embodiment exists where such a feature is included or implemented, while all examples are not limited thereto. The use of the terms “example” or “embodiment” herein have a same meaning (e.g., the phrasing “in one example” has a same meaning as “in one embodiment,” and “one or more examples” has a same meaning as “in one or more embodiments”).

Although terms such as “first,” “second,” and “third,” or A, B, (a), (b), and the like may be used herein to describe various members, components, regions, layers, or sections, these members, components, regions, layers, or sections are not to be limited by these terms. Each of these terminologies is not used to define an essence, order, or sequence of corresponding members, components, regions, layers, or sections, for example, but is used merely to distinguish the corresponding members, components, regions, layers, or sections from other members, components, regions, layers, or sections. Thus, a first member, component, region, layer, or section referred to in the examples described herein may also be referred to as a second member, component, region, layer, or section without departing from the teachings of the examples.

Hereinafter, the examples are described in detail with reference to the accompanying drawings. When describing the examples with reference to the accompanying drawings, like reference numerals refer to like components and a repeated description related thereto will be omitted.

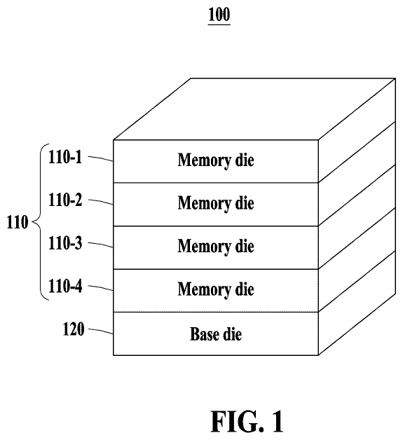

FIG. 1 illustrates an example of a semiconductor device.

Referring to FIG. 1, a semiconductor device 100 may include a memory stack 110 and a base die 120. The memory stack 110 may include a plurality of memory dies 110-1, 110-2, 110-3, and 110-4.

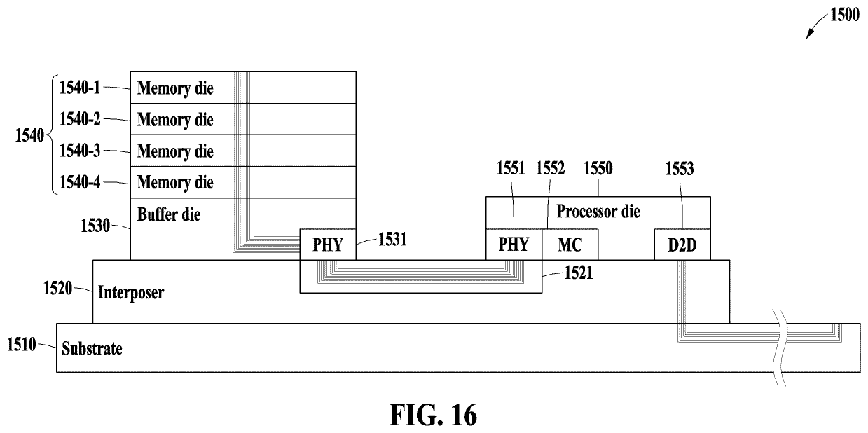

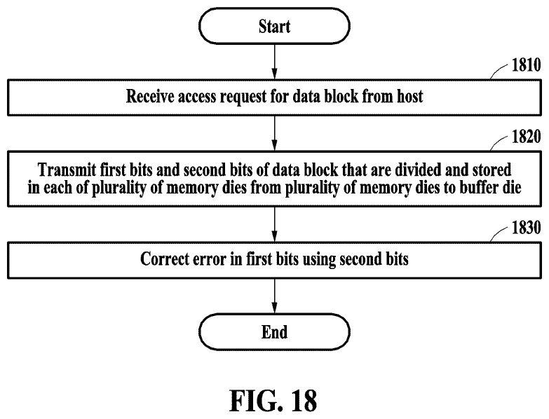

The semiconductor device 100 may be, for example, a memory device such as random-access memory (RAM), dynamic random-access memory (DRAM), and/or high bandwidth memory (HBM), but examples are not limited thereto. For example, the semiconductor device 100 may include a processor device (e.g., a three-dimensional (3D) processor) including memory. An example in which the semiconductor device 100 is a memory device and an example in which the semiconductor device 100 is a processor device are described in detail with reference to FIGS. 16 and 18, respectively.

The plurality of memory dies 110-1, 110-2, 110-3, and 110-4 may be stacked in multiple layers on the base die 120. Each of the plurality of memory dies 110-1, 110-2, 110-3, and 110-4 may store data and may transmit the stored data to a host (not shown) through the base die 120. In the present disclosure, for ease of description, a memory die may also be referred to as a core die or a C-die.

The base die 120 may relay data transmission between the memory stack 110 and the host. For example, the data stored in the plurality of memory dies 110-1, 110-2, 110-3, and 110-4 may not be directly transmitted to the host but may be transmitted to the host through the base die 120. The base die 120 of one or more embodiments may temporarily store a data signal and may regenerate and transmit a signal, thereby improving the stability and accuracy of the signal. In addition, the base die 120 of one or more embodiments may improve the data processing speed of the whole system including the semiconductor device 100 by reducing latency and signal distortion that may occur during a data transmission process. The base die 120 may be a buffer die or a processor die depending on the example. For example, when the semiconductor device 100 is HBM, the base die 120 may represent a buffer die, and when the semiconductor device 100 is a 3D processor, the base die 120 may represent a processor die. In the present disclosure, for ease of description, the base die 120 may also be referred to as a buffer die or a B-die.

The base die 120 of one or more embodiments may support smooth communication between the memory and the processor by alleviating an issue of increasing signal loss and delay as the physical distance between the memory stack 110 and the host increases. Therefore, the base die 120 of one or more embodiments may maintain the reliability of data transmission in a structure of the semiconductor device 100 and may improve system performance.

The host (not shown) may communicate with the semiconductor device 100 through wired or wireless communication and may request transmission of the data stored in the plurality of memory dies 110-1, 110-2, 110-3, and 110-4 of the semiconductor device 100. The host may include various processors such as a central processing unit (CPU), a graphics processing unit (GPU), a neural processing unit (NPU), and a tensor processing unit (TPU). The host may request access to one or more channels among memory channels of the semiconductor device 100 and may receive data from the channels to which access is requested. Depending on the example, the host may be provided separately from the semiconductor device 100 or may be implemented in the form of a processor die in the semiconductor device 100.

The plurality of memory dies 110-1, 110-2, 110-3, and 110-4 of the semiconductor device 100 may divide and store first bits that represent data of a data block for a memory channel and second bits that represent an error correcting code (ECC). In addition, each of the plurality of memory dies 110-1, 110-2, 110-3, and 110-4 may include a plurality of channel partitions and may divide and store the first bits and the second bits in any one of the plurality of channel partitions. When the data block for the memory channel is requested to be accessed from the host, the plurality of memory dies 110-1, 110-2, 110-3, and 110-4 may transmit the first bits and the second bits of the data block to the base die 120. In the present disclosure, for ease of description, the ECC may also be referred to as parity.

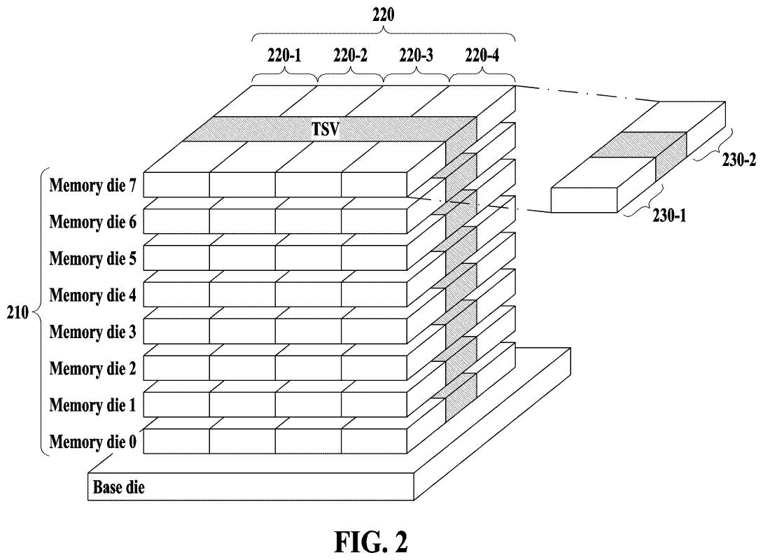

The semiconductor device 100 of one or more embodiments may divide and store the ECC and the data in the plurality of memory dies 110-1, 110-2, 110-3, and 110-4, and thus, even when a portion of memory dies is damaged or the stored data is damaged, the semiconductor device 100 of one or more embodiments may confirm whether an error occurs in the data and correct the error. In addition, the semiconductor device 100 of one or more embodiments may determine the error in the data without performance overhead and at low cost, without design changes to cells or layouts of the plurality of memory dies 110-1, 110-2, 110-3, and 110-4 or additional dies. In addition, since the ECC and the data are divided and stored in the plurality of memory dies 110-1, 110-2, 110-3, and 110-4, the semiconductor device 100 of one or more embodiments may increase the reliability, availability and serviceability (RAS) of the semiconductor device 100, and may increase the yield and expected lifetime of the semiconductor device 100. Examples of the structure and operation of dividing and storing the ECC and the data by the semiconductor device 100 are described in detail with reference to FIGS. 2 to 16.

FIG. 2 illustrates an example of a plurality of memory dies included in a semiconductor device.

Referring to FIG. 2, each of a plurality of memory dies 210 may include a plurality of reference memory channels 220. For example, a memory die 7 may include reference memory channels 220-1, 220-2, 220-3, and 220-4. In FIG. 2, only four of the plurality of reference memory channels 220 included in one memory die are illustrated, but the example is not limited thereto, and the number of reference memory channels may be any one or more.

According to an example, the number of the plurality of memory dies 210 may be determined as a power of 2 (e.g., “4”, “8”, and “16”), and first bits and second bits of a data block may be divided according to the number of the plurality of memory dies 210 and stored in the plurality of memory dies 210. For example, the first bits and the second bits may be divided into a power of 2 and stored in the plurality of memory dies 210.

According to an example, the plurality of memory dies 210 may include a plurality of channels that may operate independently of each other, and a base die may store the first bits and the second bits of the data block in a channel corresponding to the data block among the plurality of channels. In the present disclosure, for ease of description, the plurality of channels operating independently may be referred to as reference memory channels.

Each of the reference memory channels 220-1, 220-2, 220-3, and 220-4 may include one or more memory banks that may store data and an ECC. For example, a memory bank may include memory cells, a row decoder, a column decoder, and a sense amplifier that are connected to word lines and bit lines. For example, each of the reference memory channels 220-1, 220-2, 220-3, and 220-4 may include eight memory banks, but the example is not limited thereto, and the reference memory channels 220-1, 220-2, 220-3, and 220-4 may include any number of memory banks according to other non-limiting examples. According to an example, each of the plurality of memory dies 210 may divide and store data of memory channels that is requested to be accessed from a host in any one of the plurality of reference memory channels 220. In the present disclosure, for ease of description, each of the reference memory channels 220-1, 220-2, 220-3, and 220-4 may also be referred to as a cell channel.

Each of the plurality of reference memory channels 220 may include pseudo channels. For example, the reference memory channel 220-4 may include two pseudo channels 230-1 and 230-2. For example, the pseudo channels 230-1 and 230-2 may share a memory command and clock inputs (e.g., a clock signal (CK) and a clock enable signal (CKE)) of a reference memory channel but may independently decode and execute commands.

The base die and the plurality of memory dies 210 may include a through-silicon via (TSV) area. In the TSV area, TSVs may be arranged to penetrate the plurality of memory dies 210. The base die may transmit and receive signals and/or data to and from the plurality of memory dies 210 through the TSVs. Each of the plurality of memory dies 210 may transmit and receive the signals and/or the data to and from the base die and other memory dies through the TSVs. The signals and/or the data may be independently transmitted and received through the TSVs corresponding to each reference memory channel.

For example, when the host transmits the memory command and an address signal from the reference memory channel 220-1 to a memory area corresponding to a data block “A” to access data of the data block “A” stored in the reference memory channel 220-1 of the memory die 7, the base die may transmit control signals to the corresponding memory area through a command pin corresponding to the corresponding memory area, and the corresponding memory area may transmit the stored data to the base die through a TSV, thereby allowing the host to access the data block “A”. In the preceding example, for the host to access the data block “A”, the base die may perform the same operation on memory areas corresponding to the data block “A” stored in each of the plurality of memory dies 210.

The base die and the plurality of memory dies 210 may further include a control logic circuit. The control logic circuit may control access to memory banks based on the memory command and the address signal transmitted from the host and may generate control signals for accessing the memory banks. In addition, the base die may include a channel controller corresponding to each of the reference memory channels. The channel controller may manage memory reference operations of a corresponding reference memory channel and may determine timing requirements of a corresponding channel.

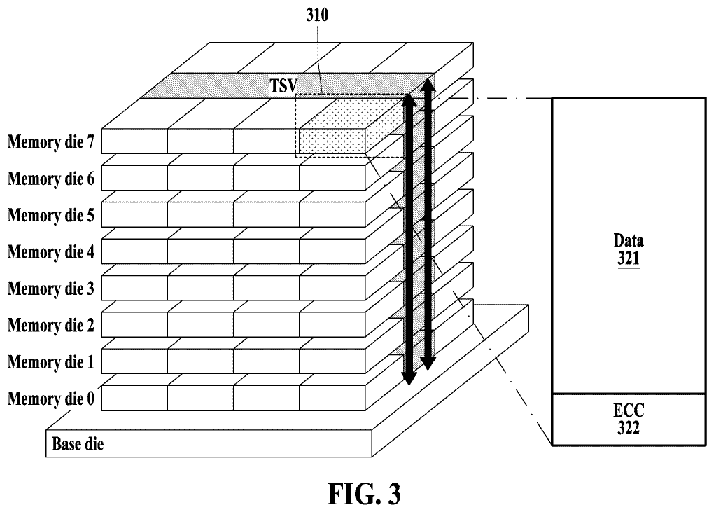

FIG. 3 illustrates an example of reference memory channels.

Referring to FIG. 3, a memory area of a reference memory channel may include a first area 321 and a second area 322. For example, in the reference memory channel, any one of pseudo channels (e.g., a pseudo channel 310) may include the first area 321 and the second area 322. As with the pseudo channel 310, other reference memory channels included in each of memory dies may also include a first area and a second area.

The first area 321 may store data of data blocks. For example, the first area 321 may store first bits that represent the data of the data blocks. For example, the first area 321 may have 32 bytes of storage space, but the example is not limited thereto, and the first area 321 may have any number of bytes of storage space according to other non-limiting examples.

The second area 322 may store an ECC of the data blocks. For example, the second area 322 may store second bits that represent the ECC of the data blocks. According to an example, the second area 322 may store an ECC added on-device in the semiconductor device design (e.g., an OD-ECC) and/or an ECC added according to a selection of a user (e.g., a META-ECC). For example, the second area 322 may have 2 bytes of storage space for the META-ECC and 4 bytes of storage space for the OD-ECC, but the example is not limited thereto, and the second area 322 may have any number of bytes of storage space according to other non-limiting examples. The ECC may be used to determine whether an error occurs in the data of the data block, but the type of the ECC and a method of determining whether an error occurs may vary depending on the example.

The first area 321 and the second area 322 may be divided into a plurality of partitions according to the number of memory channels supported. For example, when the pseudo channel 310 supports eight memory channels, the first area 321 and the second area 322 may be divided into eight partitions to store the data and the ECC corresponding to each partition. The plurality of partitions may be divided into equal sizes but may be divided into different sizes for each memory channel depending on the example.

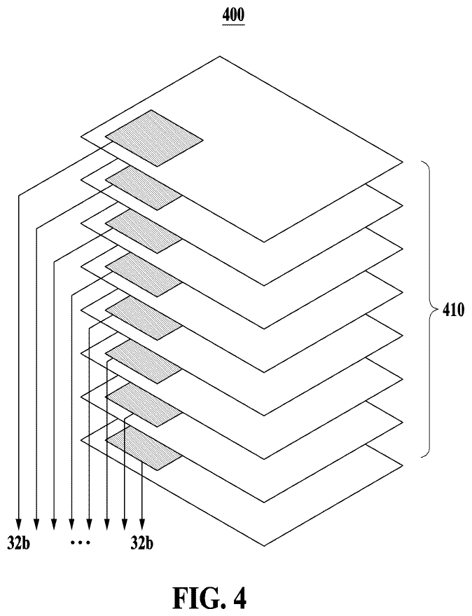

FIG. 4 illustrates an example of an operation of dividing and storing first bits and second bits by a plurality of memory dies.

Referring to FIG. 4, when access to a data block is requested, the first bits and the second bits of the data block that are divided and stored in a plurality of memory dies 410 of a memory stack 400 may be transmitted. The data block may represent a set of data read from the plurality of memory dies 410 for a data channel requested by a host. Each of data blocks may correspond to each of memory channels supported by a semiconductor device. For example, the data block may be stored at particular addresses corresponding to the requested data channel.

For example, when the second bits of 32 bits of the data block are stored in each of the plurality of memory dies 410, each of the plurality of memory dies 410 may transmit the second bits of 32 bits to a base die in response to the access request for the data block. In addition, each of the plurality of memory dies 410 may transmit the first bits and the second bits of the data block stored in each memory die to the base die in response to the access request for the data block.

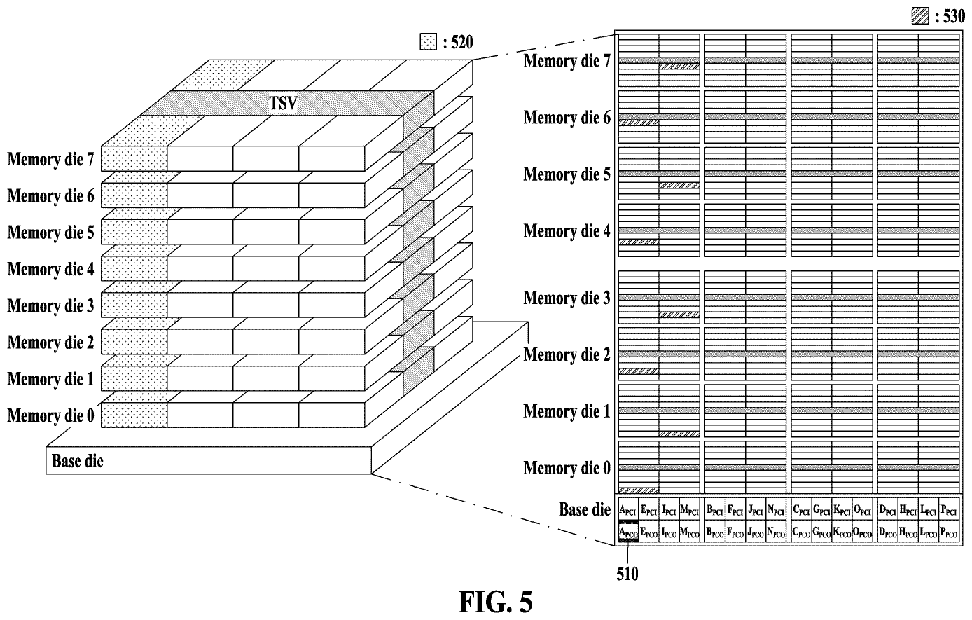

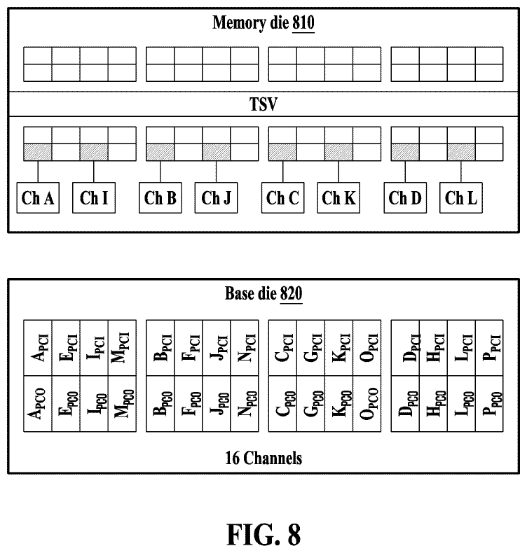

An example of the plurality of partitions that divides and stores the first bits and the second bits of the data blocks in the plurality of memory dies 410 is described in detail below with reference to FIGS. 5 and 8.

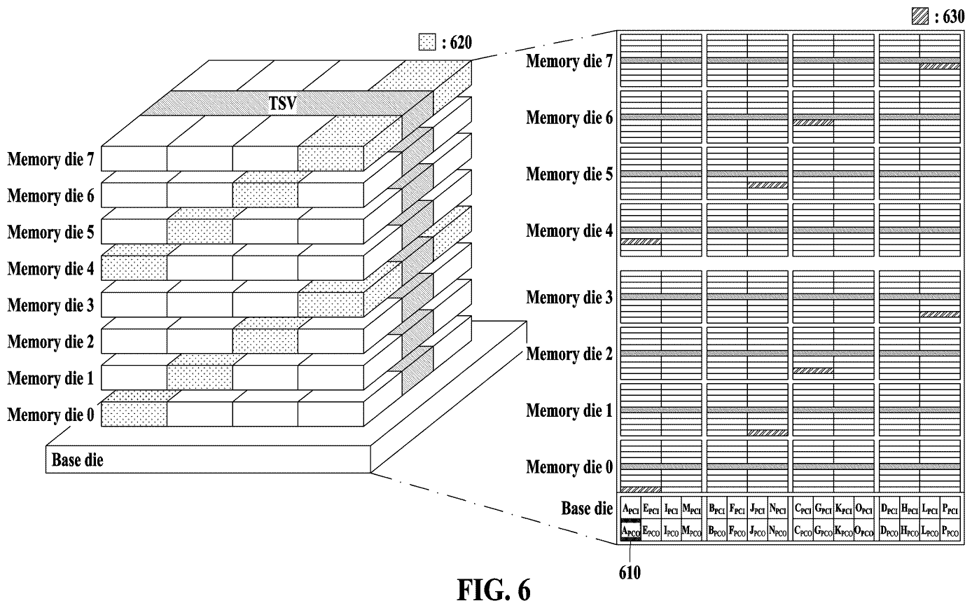

FIGS. 5 and 6 illustrate examples of a plurality of partitions.

Referring to FIG. 5, an example of a structure in which first bits and second bits of data blocks are divided and stored in a plurality of memory dies is illustrated. In the examples of FIGS. 5 and 6, for ease of description, a semiconductor device supporting “16” memory channels is illustrated in a structure in which each reference memory channel is divided into “16” partitions, but the example is not limited thereto, and the semiconductor device may support any number of memory channels according to other non-limiting examples.

In the example of FIG. 5, one reference memory channel may be divided into “16” partitions. For example, when the reference memory channel includes two pseudo-channels, each of the pseudo-channels may be divided into “8” partitions. According to an example, the first bits and the second bits of a data block 510 for one pseudo channel may be divided and stored in each of the plurality of memory dies. The data block 510 may correspond to any one of a plurality of reference memory channels of each memory die. In addition, the data block 510 may correspond to a portion of partitions 530 among partitions included in corresponding reference memory channels. The first bits and the second bits of the data block 510 may be divided and stored in the partitions 530 corresponding to the data block 510.

For example, the data block 510 may correspond to reference memory channels 520 for each memory die. In addition, the data block 510 may correspond to a portion of the partitions 530 among the partitions included in the reference memory channels 520. In this case, the first bits and the second bits of the data block 510 may be divided and stored in the corresponding partitions 530.

Reference memory channels 520 and partitions 530 corresponding to each of data blocks may be determined in advance (e.g., predetermined). A base die may be connected to the partitions 530 corresponding to a data block 510 through a command pin and/or a TSV, respectively. Alternatively or additionally, the base die may store mapping information for the reference memory channels 520 and the partitions 530 corresponding to each of the data blocks. When the data block 510 is requested to be accessed from a host, the base die may determine the partitions 530 corresponding to the data block 510 and may transmit and receive signals and/or data to and from the partitions 530. According to an example, the base die may simultaneously select the partitions 530 corresponding to the data block 510 and may access the corresponding partitions 530 simultaneously. The semiconductor device may further include additional devices or interfaces configuring the base die to access particular partitions simultaneously.

Referring to FIG. 6, as an example different from the example of FIG. 5, an example of a structure in which first bits and second bits of data blocks are divided and stored in a plurality of memory dies is illustrated. Reference memory channels 620 and partitions 630 corresponding to a data block 610 may be determined differently depending on the example.

In the example of FIG. 6, the data block 610 may correspond to the reference memory channels 620 for each memory die. In addition, the data block 610 may correspond to a portion of the partitions 630 among the partitions included in the reference memory channels 620. In this case, the first bits and the second bits of the data block 510 may be divided and stored in the corresponding partitions 630. A correspondence between data blocks and partitions may be determined dynamically depending on a layout of the semiconductor device. For example, the correspondence between data blocks and partitions may be determined differently depending on design constraints of the semiconductor device.

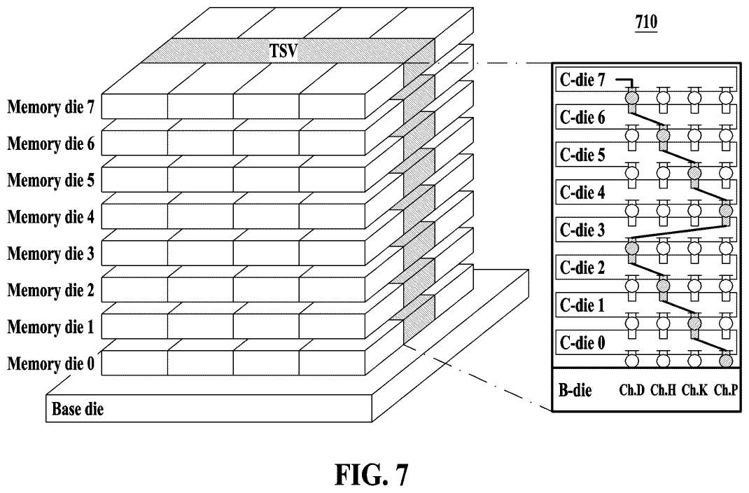

FIGS. 7 and 8 illustrate examples of a correspondence between a data block, reference memory channels, and partitions.

Referring to FIG. 7, an example of a correspondence 710 for the reference memory channels connected to each of data blocks in a TSV area is illustrated. The correspondence between the data blocks, the reference memory channels, and the partitions illustrated in FIGS. 7 and 8 is an example for description, and the example is not limited thereto.

First bits and second bits of the data blocks may be transferred from corresponding reference memory channels to a memory die through a TSV. TSVs of the reference memory channels corresponding to the same data block may be connected to each other. In the example of FIG. 7, in response to receiving an access request for a data block “Ch. P” of a particular memory channel, a base die may receive the first bits and the second bits from the reference memory channels corresponding to “Ch. P” through connected TSVs. According to an example, the base die of one or more embodiments may implement high data access granularity by dividing and receiving data from stacked base dies.

Referring to FIG. 8, an example of a correspondence between each data block of a base die 820 and partitions of a memory die 810 is illustrated. In the example of FIG. 8, the memory die 810 may represent any one of a plurality of memory dies stacked on the base die 820. However, for ease of description, a correspondence between a portion of data blocks is omitted and illustrated in the memory die 810 of FIG. 8.

For example, data blocks “Ch. A”, “Ch. B”, “Ch. C”, “Ch. D”, “Ch. I”, “Ch. J”, “Ch. K”, and “Ch. L” for each memory channel in the base die 820 may each correspond to predetermined partitions (indicated by hatched areas) of the particular memory die 810. Each partition corresponding to a particular data block may be connected to the base die 820 in an area of the corresponding data block through a command pin and a TSV. The base die 820 may transmit a memory command for a corresponding data block to a corresponding partition through the command pin, and the memory die 810 may transmit first bits and second bits stored in the partition corresponding to the corresponding data block to the base die 820 through the TSV.

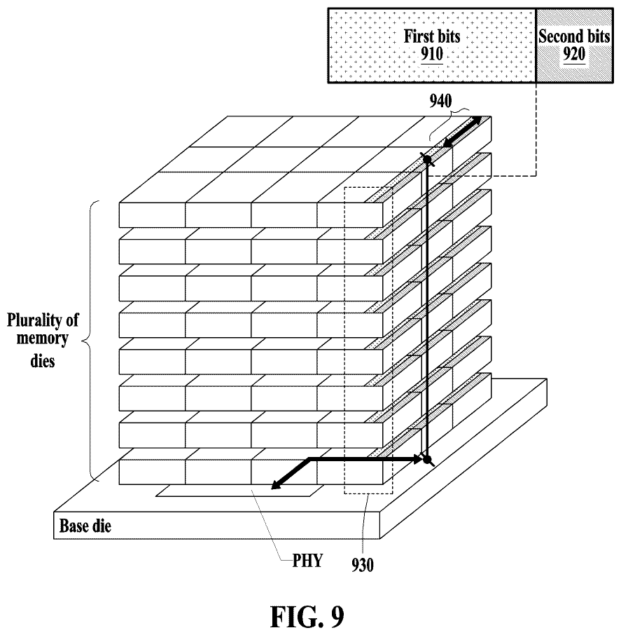

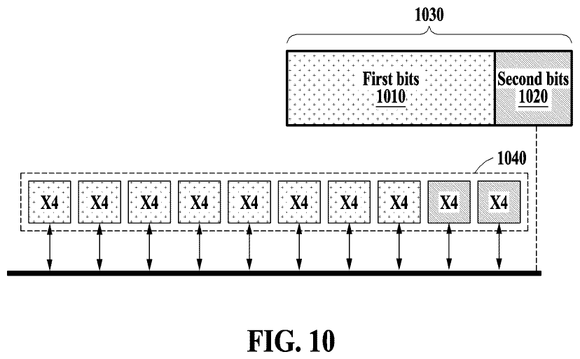

FIGS. 9 and 10 illustrate examples of an operation of transmitting first bits and second bits.

Referring to FIG. 9, first bits 910 and second bits 920 of a particular data block may be divided and stored in a plurality of memory dies. For example, the first bits 910 and the second bits 920 may be divided and stored in predetermined partitions 930 of the plurality of memory dies.

For example, when 64 bytes of data and 16 bytes of ECC of a particular data block are divided and stored in eight memory dies, each memory die may store 8 bytes of first bits and 2 bytes of the second bits of the data block. In another example, when 32 bytes of data and 12 bytes of ECC of a particular data block for any one of pseudo-channels are stored in eight memory dies, each pseudo-channel of each memory die may store 4 bytes of first bits and 1 or more bytes of second bits. In an example, each of the pseudo-channels may store the portions of first bits and second bits in a corresponding area 940 of the pseudo-channel.

A base die may include a physical layer (PHY). The PHY may include interface circuits for communicating with an external host. For example, the PHY may include interface circuits corresponding to an interface of a semiconductor device. Signals and/or data received from the host through the PHY may be transmitted to the plurality of memory dies.

Referring to FIG. 10, first bits 1010 and second bits 1020 of a data block 1030 divided and stored in each of partitions 1040 may be transmitted to a base die through the PHY. For example, the first bits 1010 and the second bits 1020 of a predetermined size (e.g., 4 bytes) may be stored in each of the partitions 1040.

According to an example, the second bits 1020 may be stored in a redundancy area in a semiconductor device. For example, by utilizing the existing redundancy area for a META-ECC and an OD-ECC in the semiconductor device, error correction of data may be possible when an issue occurs in a memory die without additional redundancy.

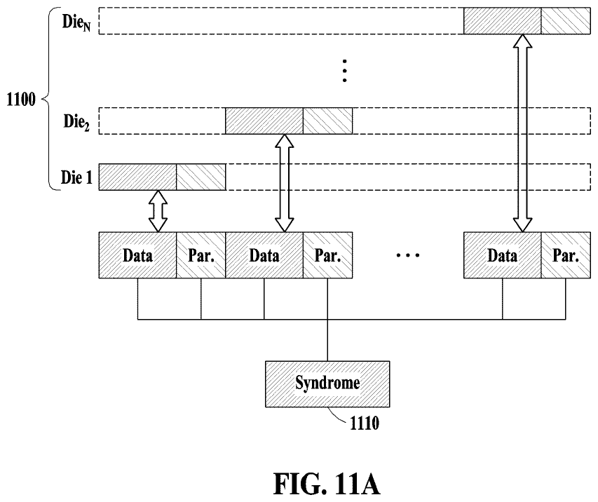

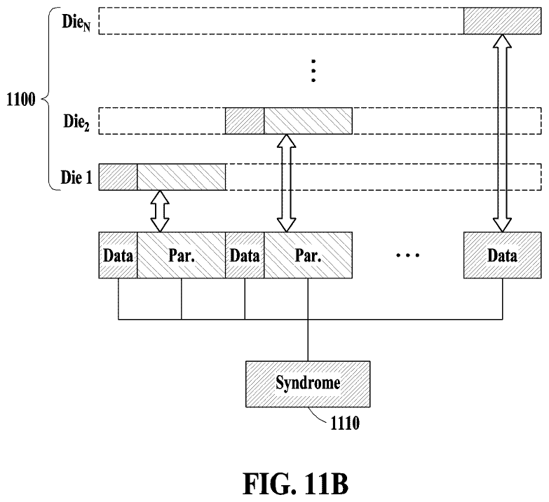

FIGS. 11A and 11B illustrate examples of an operation of determining whether an error occurs in data by using second bits.

Referring to FIG. 11A, a logic circuit 1110 of a base die may receive second bits of a data block stored in a plurality of memory dies 1100. In addition, the logic circuit 1110 may further receive first bits of the data block divided and stored in each of the plurality of memory dies 1100. According to an example, the plurality of memory dies 1100 may evenly divide and store the first bits and the second bits. For example, each of the plurality of memory dies 1100 may store 32 bits of the first bits and 11 bits of the second bits.

According to an example, a decoder of the base die may use the received second bits to determine an ECC of the data block. In the present disclosure, for ease of description, the decoder may also be referred to as an ECC decoder and/or an ECC decoder circuit. In addition, the base die may further include an encoder for encoding the ECC and storing the ECC in the plurality of memory dies 1100.

The logic circuit 1110 may determine whether an error occurs in the first bits using the ECC. The logic circuit 1110 may determine whether an error occurs in the data of the data block by determining whether an error occurred in the first bits and may correct the error. According to an example, the logic circuit 1110 may determine whether an error occurs in the data of the data block using the second bits of the data block, based on the first bits of the data block stored in channel partitions corresponding to the data block among the plurality of channel partitions. For example, the logic circuit 1110 may determine the data of the data block stored in the channel partitions corresponding to the data block as one or more symbols and may determine whether an error occurs in the first bits corresponding to each symbol based on each of the one or more symbols. For example, the logic circuit 1110 may generate a codeword using the first bits and the second bits received for the data block, may designate the first bits included in the same partition of the codeword as one or more symbols, may determine whether an error occurs using the symbols, and may correct the error. For example, the logic circuit 1110 may analyze the first bits and the second bits as symbols having a size greater than or equal to a predetermined number of bits (e.g., 2 bits), may determine whether an error occurs in the first bits, and may correct the occurred error. However, the method of determining whether an error occurs in the data of the data block and correcting the error by the logic circuit 1110 may vary depending on the example. The logic circuit 1110 may include a syndrome register (e.g., a memory syndrome register (MSR)).

According to an example, each memory die may store bits in a page unit at a row address to activate the first bits and the second bits stored in the same partition.

Referring to FIG. 11B, the plurality of memory dies 1100 may unevenly divide and store the first bits and the second bits. For example, a portion of the memory dies (e.g., including Die_{N} in FIG. 11B) among the plurality of memory dies 1100 may store only the first bits or only the second bits. The logic circuit 1110 may receive the first bits and the second bits of the data block that are unevenly divided and stored in each of the plurality of memory dies, may use the second bits to determine whether an error occurs in the first bits, and may correct the error.

For example, among the plurality of memory dies 1100, any two memory dies may store 21 bits of the first bits and 22 bits of the second bits, and the remaining memory dies may store 43 bits of the first bits. The sizes of the first bits and the second bits that each memory die divides and stores may be determined differently depending on the example.

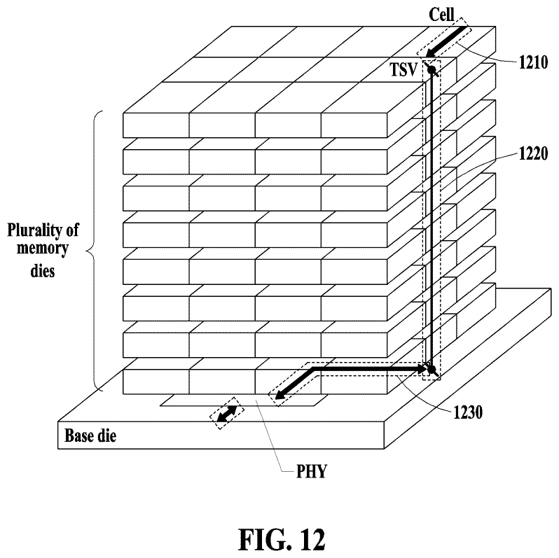

FIG. 12 illustrates an example of a redundancy area for storing second bits.

Referring to FIG. 12, a semiconductor device may store the second bits using a redundancy area provided in-memory without adding a redundancy area for a separate ECC. For example, the semiconductor device may utilize a redundancy area 1210 provided by in-DRAM of a plurality of memory dies and a redundancy area 1220 as redundancy areas for storing the second bits. For example, the redundancy area 1210 may be an OD-ECC area, and the redundancy area 1220 may be a META-ECC area. The semiconductor device may determine an ECC using the second bits received through a redundancy area 1230 of a base die.

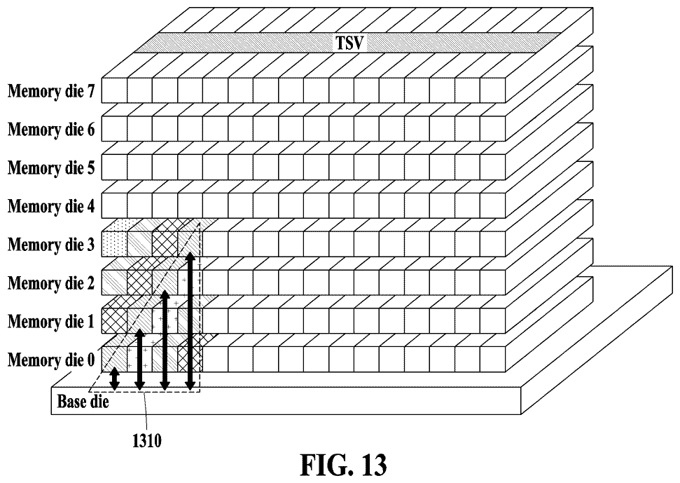

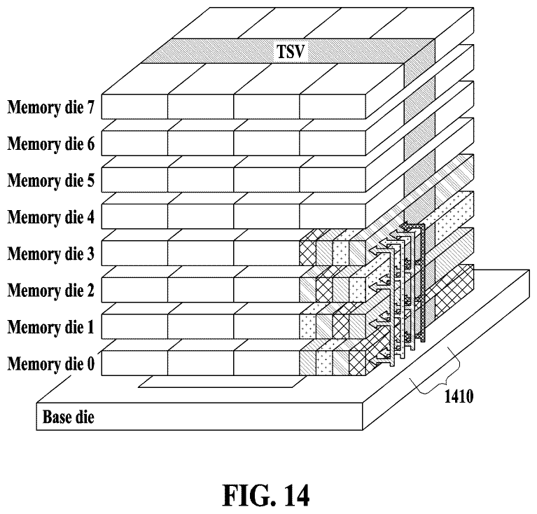

FIGS. 13 and 14 illustrate examples of an operation of transmitting bits and memory commands.

Referring to FIG. 13, each of partitions included in a plurality of memory dies may transmit first bits and second bits of a data block to a base die through TSV areas 1310. For example, when the data block is requested to be accessed from a memory die, the partitions corresponding to the data block may transmit the first bits and the second bits of the data block to the base die.

In the example of FIG. 13, when the partitions corresponding to the data block are partitions shown in hatched areas, each of the partitions may transmit the first bits and the second bits of the data block to the base die through the TSV areas 1310.

Referring to FIG. 14, the base die may transmit a memory command to the partitions corresponding to data blocks through command pins 1410 connected to each of the partitions. For example, the base die may transmit the memory command received from a host to the partitions corresponding to the memory command. Accordingly, the base die may transmit the memory command of the data block to each of the plurality of memory dies. According to an example, a command path for transmitting the memory command may be implemented through the command pins 1410 connected independently of TSVs.

In the example of FIG. 14, when the partitions corresponding to the data blocks are partitions shown in hatched areas, the base die may transmit the memory command of the data block through command pins connected to each of the partitions shown in hatched areas.

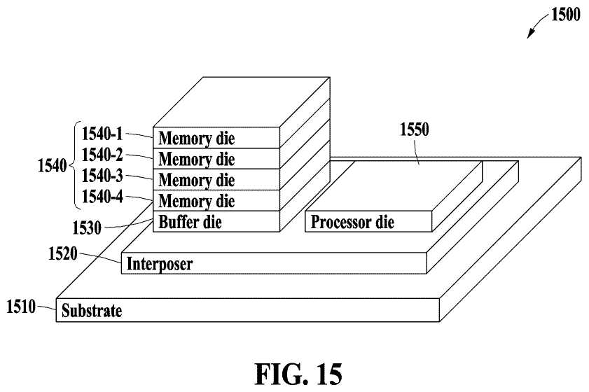

FIGS. 15 and 16 illustrate examples of a semiconductor device.

Referring to FIG. 15, an example of a semiconductor package 1500 including a semiconductor device is illustrated. According to an example, the semiconductor package 1500 may include HBM, and a base die may be or represent a buffer die 1530. The buffer die 1530 may perform operations of the above-described base die. The structure and operation of the semiconductor package 1500 are examples for description, and the examples are not limited thereto.

The semiconductor package 1500 may include a substrate 1510, a interposer 1520, the buffer die 1530, a memory stack 1540, and a processor die 1550. The memory stack 1540 may include a plurality of memory dies 1540-1, 1540-2, 1540-3, and 1540-4. The interposer 1520 may be arranged on the substrate 1510, the buffer die 1530 may be arranged on the interposer 1520, and the plurality of memory dies 1540-1, 1540-2, 1540-3, and 1540-4 may be stacked on the buffer die 1530. The processor die 1550 may be arranged adjacent to a memory die on the interposer 1520.

The interposer 1520 of the semiconductor package 1500 may be a passive element that provides electrical connection and may provide a physical wiring path for communication between the plurality of memory dies 1540-1, 1540-2, 1540-3, and 1540-4 and the processor die 1550. Here, the interposer 1520 may transmit electrical signals and may not include active circuitry.

A host may be implemented as the processor die 1550 arranged adjacent to the memory die 1540. The processor die 1550 may process data transmitted from the memory stack 1540 and may include various processors (e.g., processor cores) such as a CPU, a GPU, an NPU, and a TPU. The processor cores may be designed to efficiently perform high-performance computational tasks and may smoothly process data transmission with the memory stack 1540.

The description provided with reference to FIG. 15 may also apply to FIG. 16.

Referring to FIG. 16, an example of a structure of the semiconductor package 1500 of FIG. 15 viewed from the front is illustrated. In a structure of the semiconductor package 1500, since the memory stack 1540 and the processor die 1550 are physically apart from each other, electrical loss may occur when transmitting a signal. To compensate for the electrical loss, each of the buffer die 1530 and the processor die 1550 may include PHY circuits 1531 and 1551. Thus, the semiconductor package 1500 of one or more embodiments may maintain accuracy and stability of the signal transmitted through the PHY circuits 1531 and 1551.

The data generated by the memory stack 1540 may pass through the buffer die 1530 and may be transmitted to the processor die 1550 through the PHY circuit 1531 included in the buffer die 1530. The PHY circuit 1551 may also be included in the processor die 1550 and through the PHY circuit 1531, the signal transmitted from the memory stack 1540 may be processed by the processor die 1550.

In the processor die 1550, a memory controller (MC) 1552 configured to process the data transmitted from the memory stack 1540 and a chip-to-chip communication module (D2D) 1553 configured to communicate with other chips may be installed. The MC 1552 may manage data transmission with the memory stack 1540, and the communication module 1553 may serve to perform data transmission and reception between the processor die 1550 and other chips. The term “module” used herein may be hardware (e.g., hardware implementing software and/or firmware). The term “module” may be used interchangeably with other terms, for example, “component” and/or “circuit”. The “module” may be a minimum unit of an integrally formed component or part thereof. The “module” may be a minimum unit for performing one or more functions or part thereof. The “module” may be implemented mechanically or electronically.

A silicon bridge 1521 may be used for a more efficient electrical connection between the memory stack 1540 and the processor die 1550. Since the silicon bridge 1521 has high conducting wire density, the silicon bridge 1521 may serve to reduce signal loss that may occur during the data transmission and may improve a transmission rate. Depending on examples, the memory stack 1540 and the processor die 1550 may perform the data transmission through the interposer 1520 without using the silicon bridge 1521.

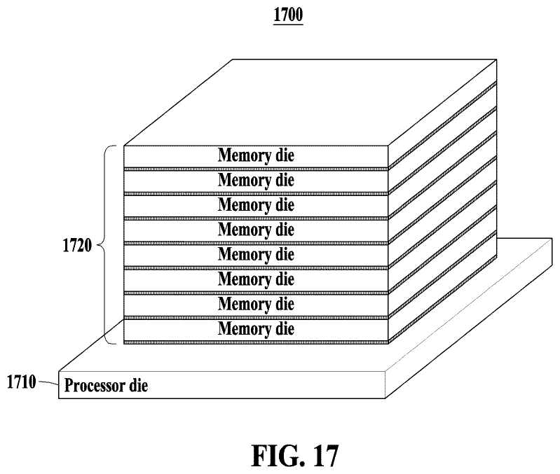

FIG. 17 illustrates an example of a semiconductor device.

Referring to FIG. 17, an example of a semiconductor package 1700 including a semiconductor device is illustrated. According to an example, the semiconductor package 1700 may represent a 3D processor, and a base die may represent a processor die 1710. In addition, a host may be a processor included in the processor die 1710. The structure and operation of the semiconductor package 1700 are examples for description, and the examples are not limited thereto.

The semiconductor package 1700 may include the processor die 1710 and a memory stack 1720. The memory stack 1720 may include a plurality of memory dies. The plurality of memory dies may be stacked on top of the processor die 1710.

According to an example, the processor die 1710 may perform operations of the above-described base die. For example, the processor die 1710 may perform the operations of the above-described base die through a processor included in the processor die 1710. For example, in response to receiving an access request for a data block from a host, the processor die 1710 may receive first bits representing data of the data block divided and stored in each of a plurality of memory dies and second bits representing an ECC. The processor die 1710 may decode the ECC using the first bits and may determine whether an error occurs in the first bits based on the ECC.

FIG. 18 illustrates an example of an operating method of a semiconductor device.

Operations 1810 to 1830 of FIG. 18 may be performed in the order and manner shown. However, the order of one or more of the operations may be changed, one or more of the operations may be omitted, two or more of the operations may be performed in parallel or simultaneously, and/or other operations may be additionally performed without departing from the spirit and scope of the example embodiments described herein. Operations 1810 to 1830 may be performed by at least one component (e.g., a processor die) of a semiconductor device.

In operation 1810, the semiconductor device may receive an access request of a data block from a host.

In operation 1820, the semiconductor device may transmit first bits representing data of a data block divided and stored in each of a plurality of memory dies and second bits representing an ECC from the plurality of memory dies to a buffer die.

In operation 1830, the semiconductor device may determine whether an error occurs in the first bits by using the second bits. The semiconductor device may determine whether an error occurs in the data of the data block by using the second bits, based on the first bits stored in channel partitions corresponding to the data block among the plurality of channel partitions. The semiconductor device may analyze the first bits and the second bits as symbols having a size greater than or equal to a predetermined number of bits, may determine whether an error occurs in the first bits, and may correct the occurred error.

The number of the plurality of memory dies may be determined as a power of 2, and first bits and second bits of a data block may be divided according to the number of the plurality of memory dies and stored in the plurality of memory dies. The plurality of memory dies may include a plurality of channels that may operate independently of each other, and a buffer die may store the first bits and the second bits of the data block in a channel corresponding to the data block among the plurality of channels. Each of the plurality of memory dies may include a plurality of channel partitions and may divide and store the first bits and the second bits of the data block in any one of the plurality of channel partitions. The data of the data block stored in the same channel partition may include one or more symbols and may determine whether an error occurs in the first bits corresponding to each symbol based on each of the one or more symbols. The plurality of channel partitions may be connected to a command pin corresponding to the data block for receiving a memory command for the data block from the buffer die. The second bits may be stored in redundancy areas included in the plurality of channel partitions.

The descriptions provided with reference to FIGS. 1 to 17 may apply to the operations shown in FIG. 18, and thus further detailed descriptions will be omitted.

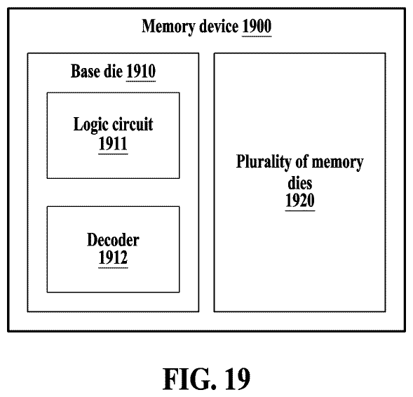

FIG. 19 illustrates an example of a semiconductor device.

Referring to FIG. 19, a semiconductor device 1900 may include a base die 1910 and a plurality of memory dies 1920. The base die 1910 may include a logic circuit 1911 (e.g., one or more processors) and a decoder 1912.

In response to receiving an access request for a data block from a host, the logic circuit 1911 may receive first bits representing data of the data block divided and stored in each of a plurality of memory dies and second bits representing an ECC. The logic circuit 1911 may transmit a memory command for requesting first bits and second bits to a channel partition storing the first bits among a plurality of channel partitions through command pins corresponding to the data block.

The decoder 1912 may decode an ECC using the first bits. The decoder 1912 may determine whether an error occurs in the first bits based on the ECC. The decoder 1912 may determine whether an error occurs in the first bits by using the first bits, based on the second bits stored in the same channel partition among the plurality of channel partitions. The decoder 1912 may analyze the first bits and the second bits as symbols having a size greater than or equal to a predetermined number of bits, may determine whether an error occurs in the first bits, and may correct the occurred error. The decoder 1912 may analyze the first bits and the second bits as symbols having a size greater than or equal to a predetermined number of bits, may determine whether an error occurs in the first bits, and may correct the occurred error.

In addition, the semiconductor device 1900 may process the operations described above.

The semiconductor devices, memory stacks, base dies, memory dies, reference memory channels, pseudo channels, logic circuits, semiconductor packages, substrates, interposers, buffer dies, processor dies, silicon bridges, PHY circuits, MCs, communication modules, decoders, semiconductor device 100, memory stack 110, base die 120, memory dies 110-1, 110-2, 110-3, and 110-4, memory dies 210, reference memory channels 220, reference memory channels 220-1, 220-2, 220-3, and 220-4, pseudo channels 230-1 and 230-2, pseudo channel 310, memory stack 400, memory dies 410, reference memory channels 520, reference memory channels 620, memory die 810, base die 820, memory dies 1100, logic circuit 1110, semiconductor package 1500, substrate 1510, interposer 1520, buffer die 1530, memory stack 1540, processor die 1550, memory dies 1540-1, 1540-2, 1540-3, and 1540-4, silicon bridge 1521, PHY circuits 1531 and 1551, MC 1552, communication module 1553, semiconductor package 1700, processor die 1710, memory stack 1720, semiconductor device 1900, base die 1910, memory dies 1920, logic circuit 1911, and decoder 1912 described herein, including descriptions with respect to respect to FIGS. 1-19, are implemented by or representative of hardware components. As described above, or in addition to the descriptions above, examples of hardware components that may be used to perform the operations described in this application where appropriate include controllers, sensors, generators, drivers, memories, comparators, arithmetic logic units, adders, subtractors, multipliers, dividers, integrators, and any other electronic components configured to perform the operations described in this application. In other examples, one or more of the hardware components that perform the operations described in this application are implemented by computing hardware, for example, by one or more processors or computers. A processor or computer may be implemented by one or more processing elements, such as an array of logic gates, a controller and an arithmetic logic unit, a digital signal processor, a microcomputer, a programmable logic controller, a field-programmable gate array, a programmable logic array, a microprocessor, or any other device or combination of devices that is configured to respond to and execute instructions in a defined manner to achieve a desired result. In one example, a processor or computer includes, or is connected to, one or more memories storing instructions or software that are executed by the processor or computer. Hardware components implemented by a processor or computer may execute instructions or software, such as an operating system (OS) and one or more software applications that run on the OS, to perform the operations described in this application. The hardware components may also access, manipulate, process, create, and store data in response to execution of the instructions or software. For simplicity, the singular term “processor” or “computer” may be used in the description of the examples described in this application, but in other examples multiple processors or computers may be used, or a processor or computer may include multiple processing elements, or multiple types of processing elements, or both. For example, a single hardware component or two or more hardware components may be implemented by a single processor, or two or more processors, or a processor and a controller. One or more hardware components may be implemented by one or more processors, or a processor and a controller, and one or more other hardware components may be implemented by one or more other processors, or another processor and another controller. One or more processors, or a processor and a controller, may implement a single hardware component, or two or more hardware components. As described above, or in addition to the descriptions above, example hardware components may have any one or more of different processing configurations, examples of which include a single processor, independent processors, parallel processors, single-instruction single-data (SISD) multiprocessing, single-instruction multiple-data (SIMD) multiprocessing, multiple-instruction single-data (MISD) multiprocessing, and multiple-instruction multiple-data (MIMD) multiprocessing.

The methods illustrated in, and discussed with respect to, FIGS. 1-19 that perform the operations described in this application are performed by computing hardware, for example, by one or more processors or computers, implemented as described above implementing instructions (e.g., computer or processor/processing device readable instructions) or software to perform the operations described in this application that are performed by the methods. For example, a single operation or two or more operations may be performed by a single processor, or two or more processors, or a processor and a controller. One or more operations may be performed by one or more processors, or a processor and a controller, and one or more other operations may be performed by one or more other processors, or another processor and another controller. One or more processors, or a processor and a controller, may perform a single operation, or two or more operations.

Instructions or software to control computing hardware, for example, one or more processors or computers, to implement the hardware components and perform the methods as described above may be written as computer programs, code segments, instructions or any combination thereof, for individually or collectively instructing or configuring the one or more processors or computers to operate as a machine or special-purpose computer to perform the operations that are performed by the hardware components and the methods as described above. In one example, the instructions or software include machine code that is directly executed by the one or more processors or computers, such as machine code produced by a compiler. In another example, the instructions or software includes higher-level code that is executed by the one or more processors or computer using an interpreter. The instructions or software may be written using any programming language based on the block diagrams and the flow charts illustrated in the drawings and the corresponding descriptions herein, which disclose algorithms for performing the operations that are performed by the hardware components and the methods as described above.

The instructions or software to control computing hardware, for example, one or more processors or computers, to implement the hardware components and perform the methods as described above, and any associated data, data files, and data structures, may be recorded, stored, or fixed in or on one or more non-transitory computer-readable storage media, and thus, not a signal per se. As described above, or in addition to the descriptions above, examples of a non-transitory computer-readable storage medium include one or more of any of read-only memory (ROM), random-access programmable read only memory (PROM), electrically erasable programmable read-only memory (EEPROM), random-access memory (RAM), dynamic random access memory (DRAM), static random access memory (SRAM), flash memory, non-volatile memory, CD-ROMs, CD-Rs, CD+Rs, CD-RWs, CD+RWs, DVD-ROMs, DVD-Rs, DVD+Rs, DVD-RWs, DVD+RWs, DVD-RAMs, BD-ROMs, BD-Rs, BD-R LTHs, BD-REs, blue-ray or optical disk storage, hard disk drive (HDD), solid state drive (SSD), flash memory, a card type memory such as multimedia card micro or a card (for example, secure digital (SD) or extreme digital (XD)), magnetic tapes, floppy disks, magneto-optical data storage devices, optical data storage devices, hard disks, solid-state disks, and/or any other device that is configured to store the instructions or software and any associated data, data files, and data structures in a non-transitory manner and provide the instructions or software and any associated data, data files, and data structures to one or more processors or computers so that the one or more processors or computers can execute the instructions. In one example, the instructions or software and any associated data, data files, and data structures are distributed over network-coupled computer systems so that the instructions and software and any associated data, data files, and data structures are stored, accessed, and executed in a distributed fashion by the one or more processors or computers.

While this disclosure includes specific examples, it will be apparent after an understanding of the disclosure of this application that various changes in form and details may be made in these examples without departing from the spirit and scope of the claims and their equivalents. The examples described herein are to be considered in a descriptive sense only, and not for purposes of limitation. Descriptions of features or aspects in each example are to be considered as being applicable to similar features or aspects in other examples. Suitable results may be achieved if the described techniques are performed in a different order, and/or if components in a described system, architecture, device, or circuit are combined in a different manner, and/or replaced or supplemented by other components or their equivalents.

Therefore, in addition to the above and all drawing disclosures, the scope of the disclosure is also inclusive of the claims and their equivalents, i.e., all variations within the scope of the claims and their equivalents are to be construed as being included in the disclosure.

What is claimed is:

1. A semiconductor device comprising:
a base die; and
a plurality of memory dies stacked on the base die,
wherein the plurality of memory dies is configured to divide and store first bits that represent data of a data block,
the plurality of memory dies is configured to divide and store second bits that represent an error correcting code (ECC) of the data block,
in response to the data block being requested to be accessed, the plurality of memory dies is configured to transmit the first bits and the second bits of the requested data block to the base die, and
the base die is configured to determine whether an error occurs in the first bits by using the second bits.

2. The semiconductor device of claim 1, wherein the base die is either one of a buffer die and a processor die.

3. The semiconductor device of claim 1, wherein
a number of the plurality of memory dies is determined as a power of 2, and
the first bits and the second bits of the data block are stored in the plurality of memory dies.

4. The semiconductor device of claim 1, wherein
the plurality of memory dies comprises a plurality of channels that operates independently of each other, and
the base die is configured to store the first bits and the second bits of the data block in a channel corresponding to the data block among the plurality of channels.

5. The semiconductor device of claim 1, wherein
each of the plurality of memory dies comprises a plurality of channel partitions, and
the first bits and the second bits of the data block are stored in any one of the plurality of channel partitions.

6. The semiconductor device of claim 5, wherein whether an error occurs in the data of the data block is determined using the second bits, based on the first bits stored in channel partitions corresponding to the data block among the plurality of channel partitions.

7. The semiconductor device of claim 6, wherein
the data of the data block stored in the channel partitions comprises one or more symbols, and
based on each of the one or more symbols, whether an error occurs in the first bits corresponding to each symbol is determined.

8. The semiconductor device of claim 5, wherein the plurality of channel partitions is connected to a command pin that corresponds to the data block and is configured to receive a memory command for the data block from the base die.

9. The semiconductor device of claim 5, wherein the second bits are stored in redundancy areas included in the plurality of channel partitions.

10. The semiconductor device of claim 5, wherein
the base die comprises:
a logic circuit configured to receive the first bits that represent the data of the data block and are divided and stored in each of the plurality of memory dies and the second bits that represent the ECC, in response to receiving an access request for the data block from a host; and
a decoder configured to decode the ECC using the first bits, and
whether an error occurs in the first bits is determined based on the ECC.

11. The semiconductor device of claim 10, wherein the decoder is configured to determine whether an error occurs in the first bits by using the first bits, based on the second bits stored in channel partitions corresponding to the data block among the plurality of channel partitions.

12. The semiconductor device of claim 10, wherein the decoder is configured to analyze the first bits and the second bits as symbols having a size greater than or equal to a predetermined number of bits, determine whether an error occurs in the first bits, and correct the occurred error.

13. The semiconductor device of claim 10, wherein the logic circuit is configured to transmit a memory command requesting the first bits and the second bits to channel partitions corresponding to the data block storing the first bits among the plurality of channel partitions through command pins corresponding to the data block.

14. The semiconductor device of claim 10, wherein each of the plurality of memory dies is configured to store the first bits or the second bits.

15. A method of operating a semiconductor device, the method comprising:
receiving an access request for a data block from a host;
transmitting first bits that represent data of the data block and are divided and stored in each of a plurality of memory dies and second bits that represent an error correction code (ECC) from the plurality of memory dies to a base die; and
determining whether an error occurs in the first bits by using the second bits.

16. The method of claim 15, wherein
a number of the plurality of memory dies is determined as a power of 2, and
the first bits and the second bits of the data block are stored in the plurality of memory dies.

17. The method of claim 15, wherein
the plurality of memory dies comprises a plurality of channels that operates independently of each other, and
the base die is configured to store the first bits and the second bits of the data block in a channel corresponding to the data block among the plurality of channels.

18. The method of claim 15, wherein
each of the plurality of memory dies comprises a plurality of channel partitions, and
the first bits and the second bits of the data block are stored in any one of the plurality of channel partitions.

19. The method of claim 18, wherein the determining of whether an error occurs comprises determining whether an error occurs in the data of the data block by using the second bits, based on the first bits stored in channel partitions corresponding to the data block among the plurality of channel partitions.

20. The method of claim 15, wherein the determining of whether an error occurs comprises analyzing the first bits and the second bits as symbols having a size greater than or equal to a predetermined number of bits, determining whether an error occurs in the first bits, and correcting the occurred error.
